(19) United States
(12) Patent Application Publication
(10) Pub. No.: US 2010/0051093 A1
(43) Pub. Date: Mar. 4, 2010

(54) GLASS PANE WITH LIGHT-CAPTURING SURFACE STRUCTURE

(75) Inventors: Nils-Peter Harder, Hameln (DE); Ulf Blieske, Edingen Neckarhausen (DE); Dirk Neumann, Herzogenrath (DE); Marcus Neander, Eschweiler (DE); Michele Schiavoni, Paris (FR); Patrick Gayout, Villemomble (FR)

Correspondence Address: OBLON, SPIVAK, MCCLELLAND MAIER & NEUSTADT, L.L.P., 1940 DUKE STREET, ALEXANDRIA, VA, 22314, US

(73) Assignee: SAINT-GOBAIN GLASS FRANCE, COURBEVOIE (FR)

(21) Appl. No.: 11/917,479

(22) PCT Filed: Jun. 13, 2006
(86) PCT No.: PCT/FR06/50550

§ 371 Date: Oct. 19, 2009

(30) Foreign Application Priority Data
Jun. 16, 2005 (DE) 10-2005-027-737.3

(51) Int. Cl. H01L 31/00

(52) U.S. Cl. 136/256

(57) ABSTRACT

Transparent panes made of glass or of synthetic material, which simultaneously create good light trapping properties by linear structural elements and allow a thermal treatment and hardening of the glass without warping. Groups of parallel elements for which the orientation of the longitudinal extension of the elements alternates from one group to another are formed globally on the surface of the substrate. Moreover, the parallel elements can include a curvature superimposed on their longitudinal extension, which makes it possible to obtain a non-oriented reflected image with a weak screen effect. These panes can be used as covering for photovoltaic components designed to use solar energy, and can also serve a decorative purpose in the construction industry, for example for glazed doors or panes for furniture.

The Invention relates to a transparent pane, a method of manufacturing a transparent pane and in particular a glass pane which is provided with a surface structure, which has the features described in the preamble of the independent pane claim.

The invention also relates to panes which have such surface structures, a device or a tool which is suitable for the implementation of the method as well as preferred uses of the panes.

The invention also relates to the assembly comprising the pane according to the invention and an element capable of collecting light energy after it has traversed said pane.

The glass can be organic (or synthetic) or inorganic, that is to say silica-based. It is in all cases made of a rigid material.

From the document EP 0 493 202 B1 are known transparent panes provided with regular surface structures in which a structure impressed in the substrate is formed of pyramid-shaped recesses that are identical to each other and which are separated from each other by distances smaller than the biggest dimension of the recesses. The pyramids or sections of pyramid which are provided in them as a motif can be produced with a hexagonal or square base area but they all have approximately flat side surfaces.

Combinations of embossings and of pyramids which protrude from their bottom have also been described. In particular, good light diffusion properties and a reduced visual detection of the presence of individual motifs which form the structure is obtained in this way due to a harmonious overall matt surface appearance.

Moreover, there is known, from the document WO 03/04 66 17 A1, the manufacture and use of transparent plates (panes) provided with surface structures in the form of geometric relief which should improve the transmission of light and the light efficiency in particular for panes which are combined with solar cells and photovoltaic solar modules in solar collectors, flat plasma discharge lamps, image projection screens and projectors. The motifs of the geometric structure can in particular be concave with respect to the overall surface of the structured side of the pane, that is to say hot rolled into the initial substrate or formed in another appropriate way. In general, the motifs are of periodic nature, unlike that which is obtained by sandblasting or by etching methods. For technical production reasons (traversing speed, tolerances in centering the axis of the fashioning cylinder, adhesion of rolled material on the cylinders, etc.) it is not however always possible to reproduce this periodicity with the desired accuracy.

Because of this, on these structured surface panes, an optical phenomena is established which consist in that the incident light is reflected differently by panes provided with the same surface motif and disposed or installed beside one another in the same plane or even within one and the same pane. In practice, depending on the fitting position, one part of the surface can reflect brilliantly and brightly whilst an immediately adjacent parallel part of surface has an almost matt appearance.

Even though this appearance is of purely visual and aesthetic nature, it does not at all degrade the traversing of the light to the elements, detectors, etc., situated on the other side of the pane.

The cause of the variation of the impression of brightness according to the position on the pane is as follows. Structures which are entirely regular in the ideal case have a characteristic reflection motif in which, for a given angle of incidence of light, the reflection takes place in completely specified directions and no reflection takes place in angular ranges which are adjacent to them. If, in a zone of the glass, because of the production tolerances mentioned above, the structures are formed on the surface of the glass in a (slightly) different manner, the characteristic direction of reflection of that zone of the glass is oriented in another direction (at another angle). The consequence is that situations appear in which an observer is in the direction of reflection for one part of the glass but not in the direction of reflection for the other part of the glass. Thus, one zone of the glass has a bright appearance (reflecting) and the other as a dark appearance. In principle, this effect also takes place on glass with a smooth surface, but which is for example curved, which also has a bright reflection appearance only at certain places for given positions of the sun and of the observer.

However, despite the inevitable manufacturing tolerances, it is possible to look for possibilities of giving these glasses a regular appearance of the light reflection in a particular mounting case. It is also known that it is possible to obtain good light trapping properties with grooves or ribs, in the surface of the substrate, whose lengthwise extension clearly exceeds the transverse dimensions. The document

U.S. Pat. No. 4,411,493 discloses a pane for building windows which must contribute to energy saving both in summer (air-conditioning) and in winter (heating). By a linear motif of parallel lines, there is obtained with this configuration a reflection or absorption behavior which strongly depends on the angle of incidence of the light. Depending on the fitting position, these surfaces are less subject to dirtying because (rain)water can flow along the grooves and thus carry solid particles.

In Solar Energy, 53, 2, pages 171 to 176, (1994), “A. Scheydecker, A. Goetsberger, V. Wittwer, Reduction of reflection losses of PV-modules by structured surfaces”, there is also described an effect of light trapping by glass surfaces structured in straight lines (grooves).

In addition to the reflection problem on regular surface structures described above, another problem can arise with long structures which extend in a straight line when glass panes which are so provided must be heat hardened. As the continuous grooves at the same time constitute non-homogeneities in the cross section of the thickness of the pane which characterize a special (preferential) direction on the surface of the glass, when these structures are present, it is not possible to prevent the glass panes from deforming or undulating and thus becoming non-flat and useless in most applications. A similar problem is known on corrugated sheets whose corrugations are similar to surface grooves and which are also characterized by the fact that a particular direction prevails over the others. Perpendicularly with respect to this direction, the corrugated sheet can be bent easily, but this cannot be done in other directions. Fundamentally, it is the same situation the result of which is that, in the glass, the stresses created in the material during the hardening give rise to flexions when one direction of the glass has stronger mechanical properties than it does in other directions.

In order to contribute to solving this problem of warping or of flexion during the hardening of the glass, it is also necessary to be attentive to the fact that a modified surface structure must also be as little subject as possible to sticking dirt and that it must be easily cleaned.

Panes having the commercial name “SGG Paint” are known whose surface has structures of the coarse brush stroke type with lines that are parallel to each other but which, for some of them, extend in straight lines and, for others, extend in arcs of circle. The individual brush stokes all have a limited length and extend in different directions which are not distinctly arranged.

The “SGG Geo” glass pattern (utility model DE 91 09 087.3) has geometric shapes which are also a plurality of lines that are parallel to each other and which are disposed in irregular meanderings with changes of direction through an angle of 30°.

Both of the known utility models of glass, which are used principally for decorative purposes for solid glass doors and as glazing for furniture have, in comparison with the fine surface structures mentioned at the beginning (which have dimensions of the order of a millimeter or less), very big dimensions (lengths, reliefs) whose details can be detected with the naked eye even at a great distance.

Moreover, these known structurings are not sufficiently deep and the angle of their flanks is not sufficiently sharp to create light trapping effects. In the embodiment of this glass utility model, there has also in fact been taken into account the fact that the panes must in any case be hardened.

The problem at the root of the invention is to propose a method of manufacturing glass panes provided with surface structures which have good light trapping properties and a low tendency to become dirty, and a low risk of distortion during heat treatments such as hardening. It will also be necessary to create a device which is particularly suitable for the implementation of the method.

In terms of method, this problem is solved according to the invention with the features of the independent method claim.

The features of the independent device claim propose a corresponding fashioning device. The features of the independent utilization claim describe a particularly preferred utilization of a transparent pane manufactured according to the method and/or with the device. The features of the secondary claims which depend on the respective independent clams give advantageous developments of the invention.

The fundamental purpose of the invention is to obtain a surface which has light trapping properties whilst having good properties of self-cleaning by the flow of water and which is suitable for heat treatment, for example the hardening of glass panes, without becoming warped.

In particular it will be necessary to avoid the formation of sharp (marked) variations in the intensity of reflection for small modifications of the angle of observation.

Fundamentally, this is obtained primarily by the fact that despite these elements which are in general elongated, the structure does not have a preferential direction of the orientation of the reflected light, which furthermore avoids the existence of weak zones from the mechanical point of view.

These elements are generally produced directly on the surface of the pane itself. They are therefore constituted from the same material as the pane itself and on its surface. These elements (or this texturing) does not therefore result from an added layer fixed to the pane. These elements can for example be of the prismatic type and, seen in cross section, these elements can for example have a triangular cross section.

In a first solution, the overall assembly is obtained by forming in the structure groups constituted by elongated elements parallel with each other (recesses/grooves and/or reliefs/ribs), each group being isolable in itself and the longitudinal orientation of the elements of two immediately successive groups being disposed obliquely with respect to each other. Unlike the known utility model “SGG Geo” mentioned above, direct transitions between elements of two adjacent groups are not obtained with this configuration.

In another solution according to the invention, the parallel elements of the structure all extend in a regular curve and preferably in the form of regular undulations.

In an advantageous development, it is also possible to form these regular curves along the longitudinal extension of parallel elements disposed in groups and thus to disperse even more strongly their reflection of light, on the one hand, and also to further optimize their light trapping effect, on the other hand.

An advantageous embodiment makes provision for curving the structural elements in the form of a crescent moon. The parallel structural elements of each group can then at the same time be nested in each other.

With advantageous developments, entirely flat surfaces (sides of pyramids, flanks of grooves in straight lines or similar) are not formed on the surface of the pane and, on the contrary, all of the reflecting surfaces are curved. Even though these curves extend along the totality of the surface of the pane, it is also possible to achieve a curve in the direction of the recess or of the relief of the elements.

The term “overall surface of the pane” means the surface or the plane of a principal surface of the pane.

Thus, the result obtained is that there are no continuous surfaces which can project a big reflection of light (a beam of parallel rays) in the same direction of observation. This consequently signifies that even in the case of small modifications of the angle of observation (or of the angle of incidence of the light), the same reflecting peak on the surface of the pane is no longer seen. Because of this large and fast variation with respect to the width or the size of the structure on the scale of the lateral lengths of the reflection directions, a reflection is thus obtained which in practice propagates in all directions and which therefore very greatly diffuses the light.

On the other hand, these shapes are however also able to trap a very large proportion of the incident light, whether this is direct radiation or diffused light. The panes thus equipped are therefore preferably suitable for coverings of elements (flat in particular) intended for using solar energy (solar cells or photovoltaic cells or bodies, such as a black body, intended to be heated by the light energy, such as for example a ducting or a reservoir containing water that is required to be heated).

At the same time, the provisions according to the invention also make it possible to ensure that the structured surface is not very subject to dirtying when the transparent panes are used outdoors (for example the particularly preferred application as covering of flat elements intended to use solar energy and which are mounted on a slope with respect to the horizontal), because between the elongated structural elements there is formed each time virtually flat narrow lines parallel with the overall surface of the substrate and which form flow channels for water.

Thus, the invention also relates to the outdoor use of the pane according to the invention, in the open air, preferably in an inclined position with respect to the horizontal, in such a way that rainwater can flow on its textured surface. In fact, the surface comprising the motifs according to the invention is intended to be facing the source of light (the sun in this case) and to capture it as much as possible in order to transmit it to a collector element situated on the other side of the pane from that facing the light source.

It is recommended to orientate the panes when they are in the mounted position such that the overall longitudinal extension of the structural elements is oriented at least obliquely with respect to the fitting slope. The overall longitudinal extension of the structural elements can be defined roughly by a connection between these end points or, in the case of undulating structural elements, by a central line about which the undulation oscillates. It is possible to consider the curvature or the undulation as a shape superimposed on the longitudinal extension of the structural elements.

The elongated and slightly curved configuration of the structural elements also automatically favors the flow of water, particularly when all of the longitudinal extensions are mounted obliquely with respect to the horizontal.

This occurs if the structural elements are produced in the form of recesses in the surface of the substrate or if they are produced such that they protrude (protrude from the latter in the form of reliefs). Mixed shapes constituted of recessed elements and elements in relief are also possible. However, in the transition or boundary zones, at least some intermediate lines will be found which are situated approximately in the initial plane of the surface of the substrate or of the pane.

The flowing water (whether this be rainwater or washing water) carries, as is known, dirt particles and thus reduces the dirt residues on the surface. With the structure of groups of elements according to the invention, even though water cannot flow simply in a straight line due to gravity and the fitting inclination, it finds its downward path in the zigzag formed between the groups or by the latter.

In a preferred development, the structural elements are assembled in groups of defined length such that each group is constituted by a defined number of parallel curved elements and preferably curved in the lengthwise direction. Each group thus has a definite optical longitudinal orientation and exhibits curved or undulating lateral lines which correspond to the curvature of the (external) elements. According to the invention, all of these groups which have alternated orientations are mutually adjoined, with no intermediate space.

The result of the latter requirement is that the groups have in general corners which from a polygon (and preferably a quadrilateral or a square) in each group.

The tight succession of the groups and the mutual offset of their orientations results in that the lateral lines of each group which are connected from both sides to the ends of the structural elements must be curved to correspond with the curvature possibly present in the structural elements, because another group offset by 90° and provided with a curved lateral edge is connected directly to each of these groups. This can be seen immediately on first examining the appended figures. The outer structural element of each group extends at an angle and preferably at a right angle with respect to the longitudinal extensions of the structural elements of the group in question.

When the individual structural elements are curves, the intermediate lines at the boundaries mentioned above between a plurality of groups can no longer extend in a straight line, but the overall direction of their extension (or alignment line) exhibits a more or less strong undulation. There is therefore no longer any continuous straight line (which would constitute a genuine groove) over the entire width or length of the pane whose thickness would be locally less than the thickness in the immediate vicinity. This absence of groove or straight line thinning the pane locally avoids the local weakening of the pane.

When the method is applied on inorganic glass panes which are hardened after production of the structuring, at the same time there is a very large avoidance of the deformation/bending of the glass pane which can occur on certain panes of the prior art during the hardening operation.

Although the applications mentioned here (photovoltaic, increasing the light trapping effect) of these surface structures prefer structuring on a single side and on a single face, and although a structuring on both faces could even be harmful with respect to the desired effect, the surface structure described here could obviously also be produced on both faces of a pane or be present on the product for a decorative purpose (for example on glazed doors or panes for furniture).

When the preferred manufacturing method is mentioned in the present description, namely by rolling only, other methods are not however excluded, for example embossing using dies or also casting in molds. It is even possible to consider using the surface structures according to the invention in the pressure injection method for panes made of synthetic material by giving an appropriate surface structure to a wall of the cavity of the injection casting mold.

A device according to the invention for the purpose of implementing the manufacturing method of these panes will consequently comprise at least one tool (a cylinder or a flat pressing surface, for example the wall of a cavity of an injection mold) on the surface of which is a negative form of the structure which must be impressed in the surface of the pane by contact with the tool.

In any case, the plastically deformable material of the pane is brought at a high temperature into contact with the tool and, by plastic deformation, the structuring which is defined by the tool progressively increases in its contact surface. The tolerances mentioned above with respect to an ideal structure obviously cannot be avoided, but they can be reduced by harmonization of the detailed structures of the tool with the behavior of the particular material of the pane.

The invention also relates to the assembly comprising the pane according to the invention and an element capable of collecting the light energy traversing said pane, said element being placed facing said pane, said pane comprising the surface structure on the side opposite to that of the said element. The pane can therefore also have a structure on both faces but this is not necessary. The surface structure is therefore imperatively at least on the side opposite to that of the light energy collecting element. The element can in particular be a photoelectric cell or a body (such as a black body) intended to be heated by the light energy, such as for example a ducting or a reservoir containing water which is desired to be heated. For the case in which the element is a photoelectric cell, the pane and the element are generally juxtaposed, a resin having a refractive index greater than that of the material constituting the pane being placed between the pane and said photoelectric cell if necessary.

Other details and advantages of the subject of the invention will emerge from the drawing of an example embodiment and from its description which is given below.

In the representations, which are simplified and not to scale:

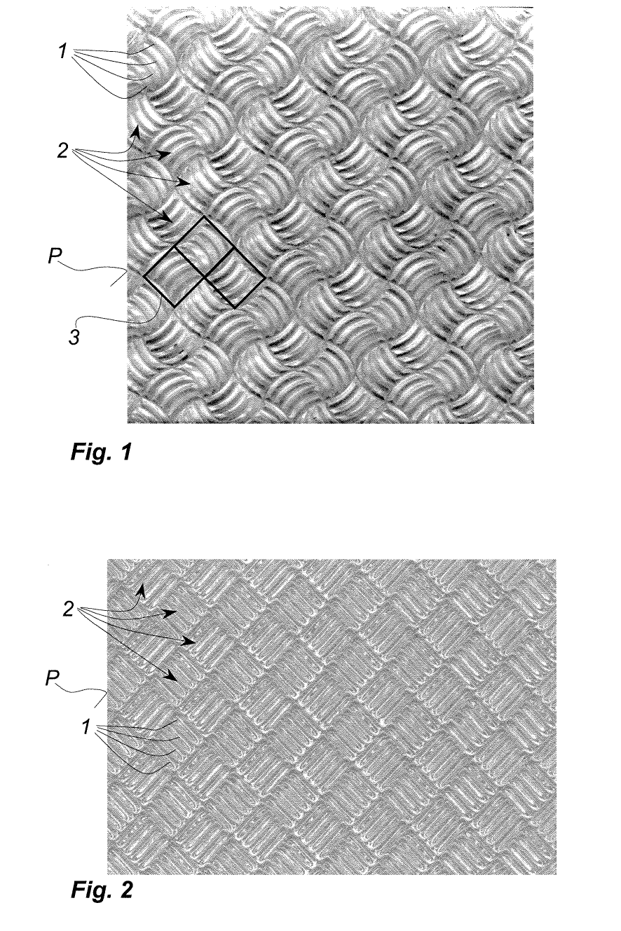

FIG. 1 shows a first embodiment of a surface structure according to the invention in which parallel curved elements of limited length are disposed in groups whose orientations are alternating,

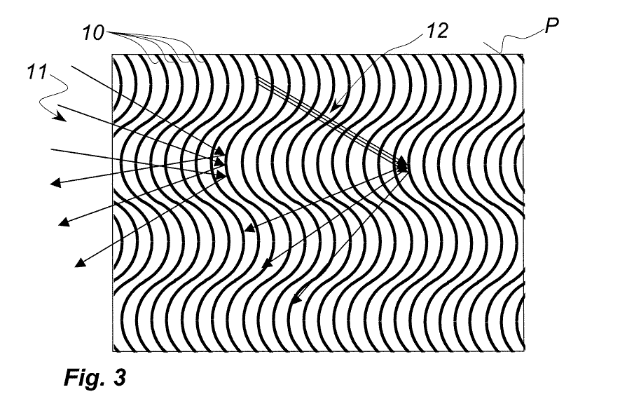

FIG. 2 shows a second embodiment of a surface structure according to the invention in which the parallel elements of limited length are not curved,

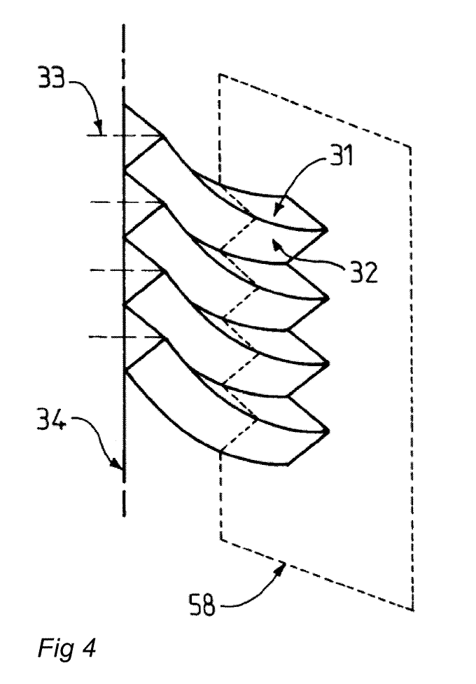

FIG. 3 shows a third embodiment of a surface structure according to the invention in which the parallel elements which extend on the surface exhibit an undulation in the direction of their length,

FIG. 4 shows a group of four parallel prismatic elements whose two principal surfaces 31 and 32 are curved in the longitudinal extension of the elements.

FIG. 1 shows an example of design of a light trapping surface structure of a pane P which is based on structures interrupted in the direction of their length or divided up into elements 1 of defined length and which essentially have just one longitudinal dimension. Each element 1 is impressed in the form of a groove in the surface of the pane. It must however be noted that it is also possible to use, within the context of the invention, elements in relief (positive elements or elements in the form of ribs) and mixed forms which have recessed elements and elements in relief.

The surface structure of the pane is there divided into surface sections or groups 2 of these elongated elements 1. These groups 2 which are all constituted by four individual elements 1 whose length is slightly curved are distributed in check pattern over the whole surface of the pane P, the orientation of the mutually adjoining groups being turned through 90° with respect to each other (in the plane of the pane or of the surface). The groups are therefore formed with a regular periodic repetition. In order to show it more clearly, three adjacent groups 2 have been surrounded by squares 3 which are defined by the corners of said groups.

In this way there is obtained the overall appearance of a checkered pattern (diagonal in the drawings) or of a “woven” surface. It must be expected that, in the image reflected in each angle of observation, the parallel incident (solar) light is reflected towards the observer only by half of the groups. This results from the alternations of orientation between the groups.

In the drawings, it is clearly seen that the groups are delimited on all their sides by oscillating lines for which the sides of the inscribed quadrilaterals form the chords. In the longitudinal extension of the elements 10, this results simply from their curvature. At the two ends of the elements, the curvature effect is imposed by the fact that the curved lateral edges of the following group must be connected to the outer elements turned through 90°.

On the other hand, FIG. 2 shows a variant which is distinguished from that of FIG. 1 by the fact that straight elements 1′ have been formed in it which are however disposed in exactly the same way in groups of four (squares) whose angle of orientation is constant, as in FIG. 1.

Even though in these preferred embodiments of FIGS. 1 and 2 the corners of each group circumscribe a square, this is not an obligatory rule. On the contrary, groups can also have perimeters shaped like long rectangles or other polygons without departing from the principle of the configuration according to the invention. They must solely comply with the condition that the groups must be able to be arranged in series in each direction, if possible without connection, and that no weakened straight line location of the type mentioned above can extend between the groups. The local parallelism of the elements in the groups is advantageous for obtaining an overall regular optical appearance of the surface.

Thus, this embodiment of the surface structure in any case has the advantage that no weakened location which extends in a straight line can be formed in the pane, because the latter has a substantially constant resistance to flexion and distortion in all directions.

The individual elements of the structure can have lengths which are adjusted to the thickness of the pane. In other words, the thicker the glass, the greater are the possible dimensions of the width of the structural elements. This dependence results from the fact that the flank angle must preferably be at least 45° and that therefore the lateral dimensions define the minimal advantageous depth. In the case of recessed structures, if it is desired to avoid “piercing” the substrate, the depth of the structure can obviously not exceed the thickness of the pane. Theory does not impose a limitation on the dimensioning in the small values direction. In practice, the short lengths limitation results from the technical conditions of fashioning the surface. In the case where the surface is fashioned in a glass rolling or casting operation, a surface structure is embossed in the hot glass at about 1000 degrees with the help of structured cylinders, it has proven to be that the smallest lateral dimensioning that can still usefully be used in practice in the current state of the art is about 1 mm.

What has been explained so far with regard to lateral dimensions relates only to the width of the structure of the individual structured elements, and therefore their extension perpendicular to the longitudinal extension of the individual structural elements. The length of the longitudinal extension can be smaller than the total length of the lateral edges of the pane, in order to ensure substantially constant mechanical properties in all directions.

FIG. 3 shows another embodiment of a surface of a pane P provided with structural elements 10 in the form of undulations which extend parallel to each other and which, in the same way as the elements 1 shown in FIGS. 1 and 2, essentially have solely one longitudinal dimension. This means here that the dimensions of the elements in the transverse direction with respect to the longitudinal direction are smaller than the value of the longitudinal extension. A cross sectional profile in the transverse direction with respect to the longitudinal extension of the structural elements 10 would give a zigzag or undulating line, the (mean) angle of the flanks being able to be modified according to requirements. Preferably, the slope of the flanks of the surface perpendicular to the local orientation of the longitudinal extension will be 45°, and the result of this is that in the cross section mentioned above, a succession of right-angled or isosceles triangles is obtained.

The surfaces of the flanks can however also rise and fall alternately, such that when the structural elements are curved in the longitudinal extension, it is possible to obtain spherically curved surfaces of flanks. Moreover, the peaks and the troughs can be flattened or rounded. In this case, it is furthermore possible to define an average flank angle which must also be at least 45°.

When the surface is configured in this way, the angle of reflection of the incident light varies very quickly along each line depending on the angle of observation, and this happens irrespective of the fact that the incident light arrives either in a diffused manner (group of arrows 20) or in parallel rays (group of arrows 30). It is thus possible to obtain good diffusion of the reflected light. In the reflected image, these undulating structural elements have an effect similar to that of short elements grouped and offset with respect to each other which was illustrated in FIG. 1.

An essential effect of this arrangement is also a high rigidity in all directions of the pane thus treated, and in particular a high resistance to flexions about an axis which extends parallel to the overall longitudinal extension of the structural elements. Unlike structural elements which extend in straight lines, no “weak points” are obtained in straight lines which could cause undulations and fracturing during the handling of the pane and, as has been mentioned, during the hardening of the glass pane structured in this way.

Despite everything, the surface structure exhibits a high flatness such that, at a rather long distance, it is not possible to see the shape of an undulating motif, depending on the fineness of the structural elements (which are produced, for example and preferably, with a width less than 1 mm).

FIG. 4 shows a group of four parallel prismatic elements whose main surfaces 31 and 32 are curved in the longitudinal extension of the elements. The cross section in the shape of a prism (triangular cross section) of these parallel elements improves the capturing of light. These elements comprise a plane of symmetry 58. Each bisector 33 contained in a plane parallel to the plane of symmetry 58 is perpendicular to the general plane of the plate 34. A plurality of these elements can be assembled as shown in FIG. 1, that is to say with extensions with alternating orientation from one group to another.

1-29. (canceled)

30. An assembly comprising:
a transparent pane having a three-dimensional surface structure comprising surface elements; and
a collector element placed facing the pane and configured to collect light energy traversing the pane,
the pane comprising the surface structure on the side opposite to that facing the collector element,
wherein the surface elements have a longitudinal extension that is essentially bigger than their extension in the transverse direction, the surface elements being such that:
either groups of parallel elements have an orientation of the longitudinal extension alternating from one group to another;
or the surface elements are formed parallel with each other and with an alternating curvature or an undulation over the totality of their longitudinal extension.

31. An assembly according to claim 30, wherein the collector element is a photoelectric cell.

32. An assembly according to claim 30, wherein the pane and the photoelectric cell are juxtaposed, a resin having a refractive index higher than that of the material constituting the pane being placed between the pane and the photoelectric cell.

33. An assembly according to claim 30, wherein groups of parallel surface elements have the orientation of the longitudinal extension alternating from one group to another, the groups configured to be inscribed within polygons.

34. An assembly according to claim 30, wherein groups of parallel surface elements have the orientation of the longitudinal extension alternating from one group to another, corners of the groups forming rectangles or squares.

35. An assembly according to claim 30, wherein groups of parallel surface elements have the orientation of the longitudinal extension alternating from one group to another, the groups formed being immediately adjacent to each other.

36. An assembly according to claim 30, wherein groups of parallel surface elements have the orientation of the longitudinal extension alternating from one group to another, the longitudinal extension of the parallel structural surface elements of the mutually adjacent groups being formed globally with an angle of 90° between them, such that a checkered visual aspect is obtained.

37. An assembly according to claim 30, wherein groups of parallel surface elements have the orientation of the longitudinal extension alternating from one group to another, the surface structural elements having a form of grooves and/or of ribs for which the slope of flanks in the transverse direction and the longitudinal extension is on average at least 45°.

38. An assembly according to claim 30, wherein groups of parallel surface elements have the orientation of the longitudinal extension alternating from one group to another, the mutually parallel elements of each group having a curvature with respect to their longitudinal extension.

39. An assembly according to claim 30, wherein groups of parallel surface elements have the orientation of the longitudinal extension alternating from one group to another, the parallel structural elements having a shape of a crescent moon.

40. An assembly according to claim 30, wherein the surface elements are formed parallel with each other and with an alternating curvature or an undulation over the totality of their longitudinal extension, the surfaces of the flanks of the structural elements having slopes modified in a direction of recesses or of reliefs.

41. An assembly according to claim 30, wherein the pane is made of glass and is thermally hardened.

42. A transparent glass pane comprising:
a three-dimensional surface structure constituted in the glass of the pane, the structure comprising surface elements formed on the surface of the pane and whose extension is essentially longitudinal and is essentially bigger than the extension of the elements in the transverse direction,
wherein groups of parallel surface elements have an orientation of the longitudinal extension of the elements alternating from one group to another.

43. A pane according to claim 42, wherein the groups are inscribed within polygons.

44. A pane according to claim 42, wherein comers of the groups form rectangles or squares.

45. A pane according to claim 42, wherein the groups are immediately adjacent to each other.

46. A pane according to claim 42, wherein the longitudinal extension of the parallel structural surface elements of mutually adjacent groups are globally formed with an angle of 90° between them, such that a checkered visual aspect is obtained.

47. A pane according to claim 42, wherein the structural surface elements are in a form of grooves and/or of ribs for which the slope of flanks in the transverse direction and the longitudinal extension is on average at least 45°.

48. A pane according to claim 42, wherein mutually parallel surface elements of each group are formed with a curvature with respect to their longitudinal extension.

49. A pane according to claim 42, wherein parallel structural surface elements have a shape of a crescent moon.

50. A pane according to claim 42, being thermally or chemically hardened.

51. A method of manufacturing a pane according to claim 42 by rolling or embossing.

52. A method according to claim 51, wherein the pane is produced by rolling using one or more cylinders that exhibit individual motifs in a form of recesses.

53. A method according to claim 51, wherein the pane is made of glass and, after embossing or rolling, the pane is thermally or chemically hardened.

54. Use of a transparent pane as a pane for covering building elements intended to use solar energy, wherein the pane comprises a three-dimensional surface structure comprising surface elements, wherein the surface elements have an essentially longitudinal extension that is bigger than their extension in the transverse direction, the surface elements being such that:
either groups of parallel elements have an orientation of the longitudinal extension alternating from one group to another; or
the elements are formed parallel with each other and with an alternating curvature or an undulation over the totality of their longitudinal extension.

55. Use according to claim 54, wherein when the pane is mounted in an inclined position with respect to the vertical, the longitudinal extension of the elements is inclined with respect to the horizontal or is inclined by 45° each time.

56. A method for collecting light and transmitting the light to a light collector element, comprising:
juxtapositioning a transparent pane with the light collector element, the pane comprising a three-dimensional surface structure comprising surface elements and a collector element placed facing the pane and configured to collect the light energy traversing the pane, the pane comprising the surface structure on the side opposite to that facing the collector element,
the surface elements having a longitudinal extension that is essentially bigger than their extension in the transverse direction, the surface elements being such that:
either groups of parallel elements have an orientation of the longitudinal extension alternating from one group to another,
or the surface elements are formed parallel with each other and with an alternating curvature or an undulation over the totality of their longitudinal extension;
the surface elements being directed towards the light source and the collector element being situated on the other side of the pane from that facing the light source.

57. A method according to claim 56, wherein the surface elements are formed parallel with each other and with an alternating curvature or an undulation over the totality of their longitudinal extension, the width of the extension perpendicular to the longitudinal extension of the individual structural elements being greater than 1 mm.

58. A method according to claim 56, wherein the surface elements are formed parallel with each other and with an alternating curvature or an undulation over the totality of their longitudinal extension, a cross sectional profile in the transverse direction with respect to the longitudinal extension of the surface giving a zigzag or undulating line.
